(19) United States
(12) Patent Application Publication
(10) Pub. No.: US 2007/0120045 A1
(43) Pub. Date: May 31, 2007

(54) Organic photoelectric conversion device and stack type photoelectric conversion device

(75) Inventor: Daisuke Yokoyama, Kanagawa (JP)

Correspondence Address: SUGHRUE-265550, 2100 PENNSYLVANIA AVE. NW, WASHINGTON, DC, 20037-3213, US

(73) Assignee: FUJI PHOTO FILM CO., LTD.

(21) Appl. No.: 11/513,046

(22) Filed: Aug. 31, 2006

(30) Foreign Application Priority Data
Aug. 31, 2005 (JP) P2005-251745

(51) Int. Cl. H01L 31/00; H03F 3/08

(52) U.S. Cl. 250/214 R; 136/263; 250/214.1

(57) ABSTRACT

An organic photoelectric conversion device comprising; a lower electrode; an organic layer; and an upper electrode provided in this order, in which at least one of the lower electrode and the upper electrode is a transparent electrode and an electron is collected in a side of one of the lower electrode and the upper electrode and a hole is collected in a side of other of the lower electrode and the upper electrode so as to read out photocurrent, wherein the electrode in the side of collecting an electron is the transparent electrode and has a word function of 4.5 eV or less.

### FIELD OF THE INVENTION

The present invention relates to an organic photo-electric conversion device having an organic layer interposed between electrodes and a so to a stack type photoelectric conversion device in a form that a photoelectric conversion layer having an organic layer interposed between electrodes is stacked on other photoelectric conversion layer. According to the invention, it is possible to provide a color imaging device which is high in sensitivity, excellent in color separation and free from false color.

### BACKGROUND OF THE INVENTION

In conventional solid-state imaging devices having a structure in which a photoelectric conversion layer is provided in substantially the same plane as a charge transfer path, there are involved defects such as optical loss in a color filter due to the progress of high integration of pixel and a phenomenon that the size becomes approximately the same size as a wavelength of light, whereby light is hardly waveguided into to a photoelectric conversion layer. Also, since three colors of RGB are detected in different positions, color separation occurs so that a false color may possibly be generated. In order to avoid this problem, an optical low-pass filter is necessary, resulting in the generation of an optical loss by this filter.

There are reported color sensors in which a stacked light receiving section of photodiodes is configured by utilizing the wavelength dependency of an absorption coefficient of Si and color separation is carried out in its depth direction (U.S. Pat. No. 5,965,875, U.S. Pat. No. 6,632,701 and JP-A-7-38136). However, there is involved such a defect that the wavelength dependency of spectral sensitivity in the stacked light receiving section is so broad that the color separation is insufficient. In particular, the color separation between blue and green colors is insufficient.

In order to solve this problem, there is proposed a system in which a sensor of green color is provided in an upper part of Si and blue a d red lights are received by Si (JP-A-2003-332551).

### SUMMARY OF THE INVENTION

In this case, in order to absorb green light and transmit blue and red lights, a photoelectric conversion layer made of an organic layer is suitable. However, it involves the following problems.

That is, in order to transmit blue and red lights even to a photodiode of Si in the lower part, it is necessary to use an electrode having high light transmittance as an electrode of the photoelectric conversion layer, and an ITO (Sn-doped indium oxide) transparent electrode is a candidacy in view of process aptitude and smoothness. However, in the case where an ITO transparent electrode is used as an electrode in the side of collecting an electron, since its work function is large as about 4.8 eV, the hole injection into the organic layer likely occurs, and in particular, a dark current remarkably increases when bias voltage is applied. Also, even if a transparent electrode of a metal oxide other than ITO is used as the transparent electrode the dark current is large, too. There are a substantially scarce number of transparent electrodes having a small work function, and even the smallest work function is approximately 4.5 eV as in AZO (Al-doped zinc oxide).

Then, an object of the invention is to obtain an organic photoelectric conversion device having a small dark current even by using a transparent electrode with high light transmittance which is made of a metal oxide or the like. Another object of the invention is to provide a stack type color photoelectric conversion device which is low in noise, high in sensitivity, excellent in color or separation and little in false color and shading by stacking an organic photoelectric conversion device having such characteristics on a separate organic photoelectric conversion device or other photoelectric conversion device.

The present inventor has become aware that even if a photoelectric conversion layer is interposed between transparent electrodes to secure light transmittance and an electrode in the side of collecting an electron is a transparent electrode with high light transmittance which made of a metal oxide, when the transparent electrode has a sufficiently small work function, a dark current as caused due to the hole injection from the transparent electrode into an organic layer can be reduced, and an organic photoelectric conversion device having a small dark current can be obtained. At the same time, by making a work function of the transparent electrode in the side of collecting a hole large, a dark current as caused due to the electron injection from the transparent electrode can be reduced, too, and an organic photoelectric conversion device having a smaller dark current can be obtained. In addition, by adjusting the work function of the electrode, a bias application voltage which is considered to be necessary for the photoelectric conversion can be controlled to a low level. Further by stacking the thus configured organic photoelectric conversion device layer on other photoelectric conversion device layer, a color photoelectric conversion device which is low in noise, high in sensitivity, excellent in color separation and little in false color and shading can be realized.

That is, the invention is achieved by the following measures.

(1) An organic photoelectric conversion device comprising a stack of a lower electrode, an organic layer and an upper electrode in this order in which at least one of the lower electrode and the upper electrode is a transparent electrode, and an electron is collected in one electrode side and a hole is collected in the other electrode side thereby reading out photocurrent, wherein the electrode in the side of collecting an electron is a transparent electrode and has a work function of 4.5 eV or less.

(2) The organic photoelectric conversion device as set forth in (1), wherein both the lower electrode and the upper electrode are a transparent electrode.

(3) The organic photoelectric conversion device as set forth in (1) or (2), wherein the electrode in the side of collecting a hole has a work function of 4.5 eV or more.

(4) The organic photoelectric conversion device as set forth in any one of (1) to (3), wherein the transparent electrode in the side of collecting an electron is a transparent electrode made of a stack of a metal oxide thin layer and a metal thin layer having a work function of not more than 4.5 eV in the organic layer side thereof.

(5) The organic photoelectric conversion device as set forth in (4), wherein the metal oxide thin layer is a thin layer of ITO (Sn-doped indium oxide).

(6) The organic photoelectric conversion device as set forth in (4) or (5), wherein the metal thin layer is a thin layer containing In, Ag or Mg.

(7) The organic photoelectric conversion device as set forth in any one of (4) to (6), wherein the metal thin layer has a thickness of from 0.5 to 10 nm.

(8) The organic photoelectric conversion device as set forth in any one of (1) to (3), wherein the transparent electrode in the side of collecting an electron is Cs-doped ITO.

(9) The organic photoelectric conversion device as set forth in any one of (1) to (3), wherein the transparent electrode in the side of collecting an electron is AZO (Al-doped zinc oxide).

(10) The organic photoelectric conversion device as set forth in any one of (1) to (3), wherein the transparent electrode in the side of collecting an electron is a lower electrode resulting from a surface treatment of ITO formed on a substrate by immersing it in an alkaline solution.

(11) The organic photoelectric conversion device as set forth in any one of (1) to (3), wherein the transparent electrode in the side of collecting an electron is a lower electrode resulting from a surface treatment of ITO formed on a substrate by sputtering it with Ar ions or Ne ions.

(12) The organic photoelectric conversion device as set forth in any one of (1) to (11), wherein the organic layer comprises a material having a quinacridone skeleton.

(13) A photoelectric conversion imaging device comprising a stack of the organic photoelectric conversion device as set forth in any one of (1) to (12) on an Si substrate having a CCD or CMOS signal transfer circuit, wherein either one of the lower electrode or the upper electrode of the organic photoelectric conversion device is connected to the signal transfer circuit, thereby reading out a signal.

(14) A stack type photoelectric conversion device comprising a stack of the organic photoelectric conversion device as set forth in any one of (1) to (12) on an Si substrate having a photodiode provided in an upper part thereof.

(15) The stack type photoelectric conversion device as set forth in (14), wherein the photodiode is configured by stacking a plural number of a first conductive region and a second conductive region which is of a conductive type opposite to the first conductive region, and a junction face between the first conductive region and the second conductive region is formed in a depth suitable for photoelectrically converting mainly lights of any two wavelength regions of blue, green and red lights, respectively.

(16) The stack type photoelectric conversion device as set forth in (14), wherein a plural number of the organic photoelectric conversion devices are stacked via an insulating layer.

(17) A stack type photoelectric conversion imaging device comprising the stack type photoelectric conversion device as set forth in any one of (14) to (16), wherein the Si substrate has a CCD or CMOS signal transfer circuit, and the lower electrode or the upper electrode of the organic photoelectric conversion device is connected to the signal transfer circuit, thereby reading out a signal.

According to the invention, by using an electrode which is transparent and small in work function as an electrode in the side of collecting an electron, even if a transparent electrode is used, an organic photoelectric conversion device having a small dark current can be obtained, and an organic photoelectric conversion device in which the hole injection from the electrode is reduced, thereby reducing a dark current can be realized while securing light transmittance, which is essential for the formation of a stack type imaging device. Also, according to the invention, by stacking an organic photoelectric conversion device with high light transmittance, a photoelectric conversion device which is low in noise, high in sensitivity, excellent in color separation and little in false color and shading can be realized. Also, by controlling a bias to be applied to the organic conversion layer to a low level, the consumed electricity can be reduced.

### BRIEF DESCRIPTION OF THE DRAWINGS

FIGS. 1A, 1B and 1C are energy diagram to explain the effect of the work function adjustment of electrodes of the invention.

FIG. 2 is a view to show a configuration example of an organic photoelectric conversion device of the invention.

FIG. 3 is a view to show a configuration example of a stack type photoelectric conversion device resulting from stacking a layer of an organic photoelectric conversion device of the invention on an Si substrate including two photodiodes in the depth direction.

FIG. 4 is a view to show a configuration example of a stack type photoelectric conversion device resulting from stacking a layer of an organic photoelectric conversion device of the invention on an Si substrate including two photodiodes in the lateral direction.

FIG. 5 is a view to show a configuration example of a stack type photoelectric conversion device in which a layer of an organic photoelectric conversion device of the invention is stacked for all of three colors.

### DETAILED DESCRIPTION OF THE INVENTION

In a photoelectric conversion device having a structure that an organic layer, quinacridone for example, is interposed between two upper and lower transparent electrodes, in the case where a transparent electrode with high transparency such as ITO is used especially as the electrode in the side of collecting an electron, a dark current is considerably large as approximately 10 μA/cm² when bias voltage of 1 V is applied on it.

It is thought that one of the causes of the generation of a dark current resides in a current which flows in the organic layer from the electrode when bias voltage is applied. In the case where an electrode with high transparency such as an ITO transparent electrode is used as the electrode in the side of collecting an electron, it is thought that since its work function is relatively large, the barrier of the hole injection into the organic layer becomes low, whereby the hole injection into the organic layer is easy to occur. Actually, in examining the work function of a metal oxide based transparent electrode with high transparency such as ITO, for example, it is known that an ITO electrode has a work function of approximately 4.8 eV, a value of which is considerably high as compared with a work function of an Al (aluminum) electrode which is approximately 4.3 eV; and that transparent electrodes of a metal oxide other than ITO have a relatively large work function as from about 4.6 to 5.4 eV exclusive of AZO (Al-doped zinc oxide) having the smallest work function as approximately 4.5 eV (see, for example, FIG. 12 of J. Vac. Sci. Technol., A17(4), July/August 1999, pages 1765 to 1772).

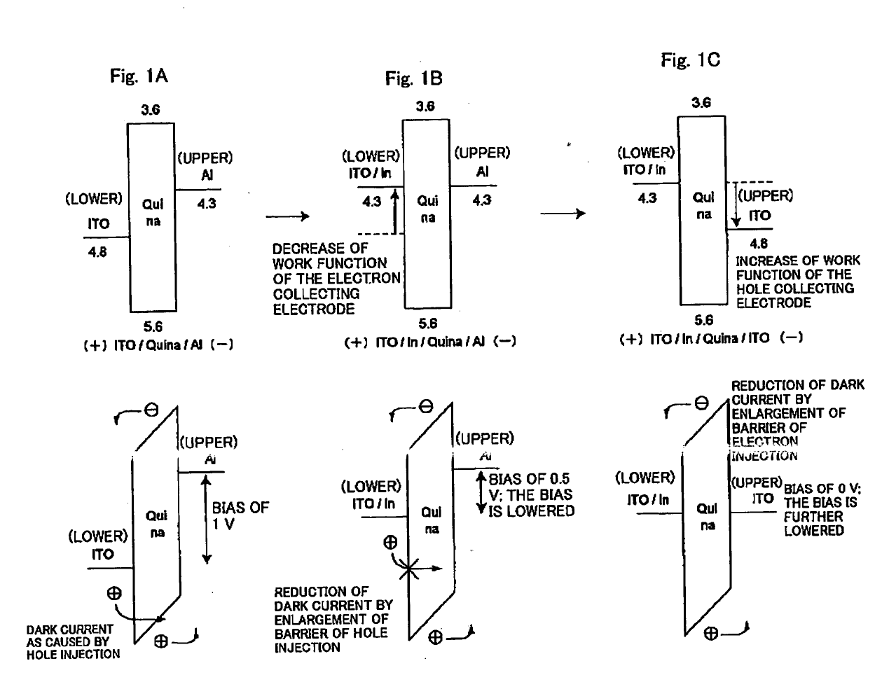

Further, for example, as illustrated in FIG. 1A, since the work function of the electron collecting electrode (ITO) is relatively large (4.8 eV), the barrier of the hole injection into the organic layer is low, and the hole injection from the ITO electrode into the organic layer (quinacridone) is easy to occur. As a result, it is thought that the dark current becomes large.

Then, in the invention, a photoelectric conversion device having a structure that an organic layer is interposed between two upper and lower electrodes is employed; at least the electrode in the side of collecting an electron in a transparent electrode; a hole is collected by the electrode in the other side; and the transparent electrode for collecting an electron is regulated to have a work function of not more than 4.5 eV.

Incidentally, the “transparent electrode” as referred to herein means an electrode capable of transmitting 80% or more of light in a visible region of from 420 nm to 660 nm as a whole (hereinafter referred to as “visible light transmittance of 80% or more”).

In the invention, nevertheless the electrode in the side of collecting an electron is a transparent electrode, in order to regulate its work function at not more than 4.5 eV, for example, the following embodiments are enumerated.

(1) A transparent electrode which is configured to have a stack of a conductive transparent metal oxide thin layer and a metal thin layer having a work function of not more than 4.5 eV in its organic layer side is used as the transparent electrode for collecting an electron.

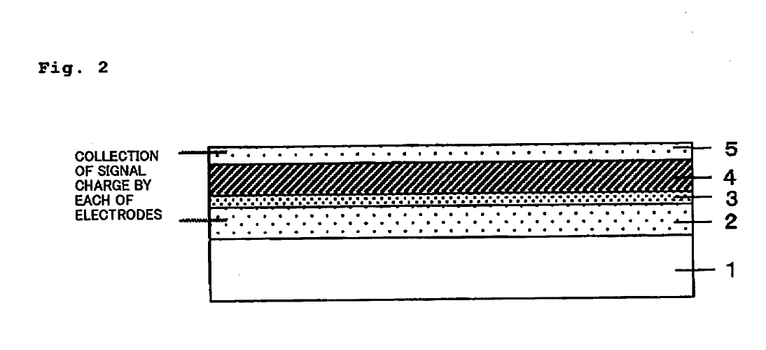

For example, ITO is used as the conductive transparent metal oxide thin layer, and a thin layer containing In, Ag or Mg is used as the metal thin layer having a work function of not more than 4.5 eV (see FIGS. 1B and 1C and FIG. 2).

(2) A conductive transparent metal oxide thin layer having a work function of not more than 4.5 eV is used as the transparent electrode for collecting an electron.

For example, an AZO thin layer having a work function of 4.5 eV is used as the conductive transparent metal oxide thin layer.

(3) A transparent electrode resulting from doping on a metal oxide to have a work function of not more than 4.5 eV is used as the transparent electrode for collecting an electron.

For example, an electrode resulting from doping Cs on ITO as the conductive metal oxide to have a work function of not more than 4.5 eV is used.

(4) An electrode resulting from a surface treatment of a conductive transparent metal oxide thin layer to have a work function of not more than 4.5 eV is used as the transparent electrode for collecting an electron.

For example, an electrode resulting from a surface treatment of ITO as the conductive transparent metal oxide thin layer by immersing it in an alkaline solution is used.

Also, an electrode resulting from a surface treatment of ITO as the conductive transparent metal oxide thin layer by sputtering it with Ar ions or Ne ions is used.

Examples of documents regarding the adjustment of the work function of the ITO electrode will be given below.

TABLE 1
Examples of documents regarding the adjustment of work function of ITO electrode (non-patent documents)

| | | | Change in work | | |
|---|---|---|---|---|---|
| Document | Authors | Method | function | Evaluation method | Factor of change |
| Applied Physics | F. Nuesch, et al. | After O₂ (Ar) plasma | 5.1 eV at maximum | Ultraviolet | Formation of electric |
| Letters, 74, 880 | | treatment, acid or | by acid treatment or | photoelectron | double layer as |
| (1999) | | alkali treatment | 3.9 eV at minimum by | spectroscopy | caused due to H⁺/OH⁻ |
| | | | alkali treatment | | adsorption on the |
| | | | | | surface |
| Synthetic Metals, 96, | T. Osada, et al. | After solvent | 4.8 eV by H₂O₂ | Ultraviolet | Reduction of O ratio |
| 77 (1998) | | washing and H₂O₂ | treatment and 4.0 eV | photoelectron | of the surface by Ne⁺ |
| | | treatment, Ne⁺ | by Ne⁺ sputtering | spectroscopy | sputtering |
| | | sputtering | | | |
| Journal of Applied | K. Suglyama, et al. | UV ozone treatment | 4.75 eV by UV ozone | Ultraviolet | Elimination of C |
| Physics, 87, 295 | | or Ar⁺ sputtering | treatment or 4.3 eV | photoelectron | contamination by UV |
| (2000) | | | by Ar⁺ sputtering | spectroscopy | ozone or reduction of |
| | | | | | O ratio by Ar⁺ |
| | | | | | sputtering |
| Applied Surface | J. A. Chaney, et al. | O₂ plasma treatment | 5.0 eV by O₂ plasma | Oscillation capacity | Formation of electric |
| Science, 218, 258 | | or alkali treatment | treatment or 4.5 eV | method (Kelvin | double layer as |
| (2003) | | | alkali treatment | method) | caused due to OH⁻ |
| | | | | | adsorption |
| Japanese Journal of | T. Uchida, et al. | Mixing of Cs vapor in | 4.1 eV at minimum by | Atmospheric | Doping of Cs into ITO |
| Applied Physics, 44, | | Ar gas for sputtering | mixing of Cs vapor | photoelectron | |
| 5939 (2005) | | at the time of ITO film | | spectroscopy | |
| | | formation | | | |

Furthermore, metals having a work function of not more than 4.5 eV will be enumerated below along with characteristics thereof.

TABLE 2
Characteristics of metal having a small work function (excluding alkali metals)

| | | | | Bulk resistivity | |
|---|---|---|---|---|---|
| | Work function (eV) | Melting point (° C.) | Boiling point (° C.) | (Ωcm) | Reaction with air or water |
| Ag | 4.2 | ◯: 950 | ◯: 2210 | ◯: 1.5 × 10⁻⁶ | ◯: Inert |
| Al | 4.3 | ◯: 660 | ◯: 2470 | ◯: 2.5 × 10⁻⁶ | Δ: Oxide layer formed |
| Ba | 2.5 | ◯: 730 | ◯: 1640 | Δ: 4.6 × 10⁻⁵ | X: Oxidized and soluble in water |
| Bi | 4.2 | ◯: 270 | ◯: 1610 | X: 1.1 × 10⁻⁴ | ◯: Inert |
| Ca | 2.9 | ◯: 840 | ◯: 1480 | ◯: 3.2 × 10⁻⁶ | X: Oxidized and soluble in water |
| Eu | 2.5 | ◯: 820 | ◯: 1600 | Δ: 9.0 × 10⁻⁵ | X: Oxidized and soluble in water |
| Ga | 2.6 | X: 28 | ◯: 2400 | Δ: 1.4 × 10⁻⁵ | ◯: Inert |
| Hf | 3.9 | ◯: 2230 | Δ: 5200 | Δ: 3.5 × 10⁻⁵ | Δ: Oxide layer formed |
| In | 4.1 | ◯: 160 | ◯: 2080 | ◯: 8.0 × 10⁻⁶ | ◯: Inert |
| La | 3.5 | ◯: 920 | ◯: 3460 | ◯: 5.7 × 10⁻⁶ | X: Oxidized and soluble in water |
| Lu | 3.3 | ◯: 1660 | ◯: 3400 | Δ: 7.9 × 10⁻⁵ | X: Oxidized and soluble in water |
| Mg | 3.7 | ◯: 650 | ◯: 1090 | ◯: 3.9 × 10⁻⁶ | X: Oxidized |
| Mn | 4.1 | ◯: 1240 | ◯: 1960 | X: 2.6 × 10⁻⁴ | X: Oxidized and soluble in water |
| Nb | 4.3 | ◯: 2470 | Δ: 4740 | Δ: 1.3 × 10⁻⁵ | Δ: Oxide layer formed |
| Nd | 3.2 | ◯: 1020 | ◯: 3070 | Δ: 6.4 × 10⁻⁵ | X: Soluble in water |
| Pb | [symbol] | ◯: [symbol] | ◯: 1710 | Δ: [symbol] × 10⁻⁵ | X: Oxidized |
| Sc | 3.5 | ◯: 1540 | ◯: 2830 | Δ: 6.1 × 10⁻⁵ | X: Oxidized and soluble in water |
| Sm | 2.7 | ◯: 1080 | ◯: 1790 | Δ: 8.8 × 10⁻⁵ | X: Soluble in water |
| Sn | 4.5 | ◯: 230 | ◯: 2270 | Δ: 9.4 × 10⁻⁵ | ◯: Inert |
| Ta | 4.3 | ◯: 3000 | Δ: 5430 | Δ: 1.2 × 10⁻⁵ | ◯: Inert |
| Tb | 3.0 | ◯: 1360 | ◯: 3120 | | X: Oxidized and soluble in water |
| Th | 3.4 | ◯: 1750 | Δ: 4790 | Δ: 1.3 × 10⁻⁵ | X: Ignited |
| Tl | 4.3 | ◯: 1660 | ◯: 3290 | Δ: 5.8 × 10⁻⁵ | ◯: Inert |
| V | 4.3 | ◯: 1890 | ◯: 3377 | Δ: 2.5 × 10⁻⁵ | ◯: Inert |
| W | 4.4 | ◯: 3410 | Δ: 5660 | ◯: 4.9 × 10⁻⁵ | ◯: Inert |
| Y | 3.1 | ◯: 1520 | Δ: 3340 | Δ: 5.7 × 10⁻⁵ | X: Oxidized |
| Zn | 4.3 | ◯: 420 | Δ: 910 | ◯: 5.5 × 10⁻⁶ | X: Oxidized |
| Zr | 4.1 | ◯: 1850 | Δ: 4380 | Δ: 4.0 × 10⁻⁵ | Δ: Oxide layer formed |

| | Material | Viewpoint |
|---|---|---|
| Preferable | Ag, Al, Ca, In, Mg | The resistance is small; the melting point is not excessively low; the |
| | | boiling point is not excessively high; and the metal is relatively cheap. |
| Especially preferable | Ag, In, Mg | The transparency is high. |
| Most preferable | Ag, In | The reactivity is low. |

(Organic Photoelectric Conversion Device)

The organic photoelectric conversion device of the invention will be simply described below.

The organic photoelectric conversion device of the invention includes an electromagnetic wave absorption/photoelectric conversion site made of an organic layer.

The electromagnetic wave absorption/photoelectric conversion site made of an organic layer is able to absorb light, thereby achieving photoelectric conversion. Usually, the electromagnetic wave absorption/photoelectric conversion site made of an organic layer is able to absorb a part of visible light (light in a wavelength region of from 420 nm to 660 nm) and preferably has an absorptance of a peak wavelength in that wavelength region of 50% or more.

In the case where the photoelectric conversion device is comprised of an electromagnetic wave absorption/photoelectric conversion site and a charge storage of charge as generated by photoelectric conversion/transfer/and read-out site, thought the charge storage/transfer/and read-out site may be provided above or beneath of the electromagnetic wave absorption/photoelectric conversion site, usually it is provided beneath the electromagnetic wave absorption/photoelectric conversion site. In the case where the electromagnetic wave absorption/photoelectric conversion site as the inorganic layer is provided in a lower layer, it is preferred that this inorganic layer also serves as the charge storage/transfer/read-out site.

(Organic Layer)

The organic layer will be hereunder described. The electromagnetic wave absorption/photoelectric conversion site made of an organic layer is made of an organic layer which is interposed between a pair of electrodes. The organic layer is formed by superposing or mixing a site for absorbing electromagnetic waves, a photoelectric conversion site, an electron transport site, a hole transport site, an electron blocking site, a hole blocking site, a crystallization preventing site, an electrode, an interlaminar contact improving site, and so on. It is preferable that the organic layer contains an organic p-type compound or an organic n-type compound.

The organic p-type semiconductor (compound) is an organic semiconductor (compound) having donor properties and refers to an organic compound which is mainly represented by a hole transport organic compound and which has properties such that it is liable to provide an electron. In more detail, the organic p-type semiconductor refers to an organic compound having a smaller ionization potential in two organic compounds when they are brought into contact with each other and used. Accordingly, with respect to the organic compound having donor properties, any organic compound can be used so far as it is an electron donating organic compound. Useful examples thereof include triarylamine compounds, benzidine compounds, pyrazoline compounds, styrylamine compounds, hydrazone compounds, triphenylmethane compounds, carbazole compounds, polysilane compounds, thiophene compounds, phthalocyanine compounds, cyanine compounds, merocyanine compounds, oxonol compounds, polyamine compounds, indole compounds, pyrrole compounds, pyrazole compounds, polyazylene compounds, fused aromatic carbocyclic compounds (for example, naphthalene derivatives, anthracene derivatives, phenanthrene derivatives, tetracene derivatives, pyrene derivatives, perylene derivatives, and fluoranthene derivatives), and metal complexes having, as a ligand, a nitrogen-containing heterocyclic compound. Incidentally, the invention is not limited to these compounds, and as described previously, an organic compound having a smaller ionization potential than that of an organic compound to be used as an n-type compound (having acceptor properties) may be used as the organic semiconductor having donor properties.

The organic n-type semiconductor (compound) is an organic semiconductor (compound) having acceptor properties and refers to an organic compound which is mainly represented by an electron transport organic compound and which has properties such that it is liable to accept an electron. In more detail, the organic n-type semiconductor refers to an organic compound having a larger electron affinity in two organic compounds when they are brought into contact with each other and used. Accordingly, with respect to the organic compound having acceptor properties, any organic compound can be used so far as it is an electron accepting organic compound. Useful examples thereof include fused aromatic carbocyclic compounds (for example, naphthalene derivatives, anthracene derivatives, phenanthroline derivatives, tetracene deriveatives, pyrene derivatives, perylene derivatives, and fluoranthene derivatives), 5- to 7-membered heterocyclic compounds containing a nitrogen atom, an oxygen atom or a sulfur atom (for example, pyridine, pyrazine, pyrimidine, pyridazine, triazine, quinoline, quinoxaline quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyralidine, pyrrolopyridine, thiadiazolopyridine, dibenzazopine, and tribenzazepine), polyarylene compounds, fluorene compounds, cyclopentadiene compounds, silyl compounds, and metal complexes having, as a ligand, a nitrogen-containing heterocyclic compound. Incidentally, the invention is not limited to these compounds, and as described previously, an organic compound having a larger electron affinity than that of an organic compound to be used as an organic compound having donor properties may be used as the organic semiconductor having acceptor properties.

Though any organic dye is useful as the p-type organic dye or n-type organic dye, preferred examples thereof include cyanine dyes, styryl dyes, hemicyanine dyes, merocyanine dyes (inclusive of zeromethinemerocyanine (simple merocyanine)), trinuclear merocyanine dyes, tetranuclear merocyanine dyes, rhodacyanine dyes, complex cyanine dyes, complex merocyanine dyes, alopolar dyes, oxonol dyes, hemioxonol dyes, squarylium dyes, croconium dyes, azamethine dyes, coumarin dyes, arylidene dyes, anthraquinone dyes, triphenylmethane dyes, azo dyes, azomethine dyes, spiro compounds, metallocene dyes, fluorenone dyes, flugide dyes, perylene dyes, phenazine dyes, phenothiazine dyes, quinone dyes, indigo dyes, diphenylmethane dyes, polyene dyes, acridine dyes, acridinone dyes, diphenylamine dyes, quinacridone dyes, quinophthalone dyes, phenoxazine dyes, phthaloperylene dyes, porphyrin dyes, chlorophyll dyes, phthalocyanine dye, metal complex dyes, and fused aromatic carbocyclic compounds (for example, naphthalene derivatives, anthracene derivatives, phenanthrene derivatives, tetracene derivatives, pyrene derivatives, perylene derivatives, and fluoranthene derivatives).

Next, the metal complex compound will be described. The metal complex compound is a metal complex having a ligand containing at least one of a nitrogen atom, an oxygen atom and a sulfur atom as coordinated to a metal. Though a metal ion in the metal complex is not particularly limited, it is preferably a beryllium ion, a magnesium ion, an aluminum ion, a gallium ion, a zinc ion, an indium ion, or a tin ion; more preferably a beryllium ion, an aluminum ion, a gallium ion, or a zinc ion; and further preferably an aluminum ion or a zinc ion. As the ligand which is contained in the metal complex, there are enumerated various known ligands. Examples thereof include ligands as described in H. Yersin, Photochemistry and Photophysics of Coordination Compounds, Springer-Verlag, 1987; and Akio Yamamoto, Organometallic Chemistry—Principles and Applications, Shokabo Publishing Co., Ltd., 1982.

The foregoing ligand is preferably a nitrogen-containing heterocyclic ligand (having preferably from 1 to 30 carbon atoms, more preferably from 2 to 20 carbon atoms, and especially preferably from 3 to 15 carbon atoms, which may be a monodentate ligand or a bidentate or polydentate ligand, with a bidentate ligand being preferable; and examples of which include a pyridine ligand, a hipyridyl ligand, a quinolinol ligand, and a hydroxyphenylazole ligand (for example, a hydroxyphenylbenzimidazole ligand, a hydroxyphenylbenzoxazole ligand, and a hydroxyphenylimidazole ligand), an alkoxy ligand (having preferably from 1 to 30 carbon atoms, more preferably from 1 to 20 carbon atoms, and especially preferably from 1 to 10 carbon atoms, examples of which include methoxy, ethoxy, butoxy, and 2-ethylhexyloxy), an aryloxy ligand (having preferably from 6 to 30 carbon atoms, more preferably from 6 to 20 carbon atoms, and especially preferably from 6 to 22 carbon atoms, examples of which include phenyloxy, 1-naphthyloxy, 2-naphthyloxy, 2,4,6-trimethylphenyloxy, and 4-biphenyloxy), an aromatic heterocyclic oxy ligand (having preferably from 1 to 30 carbon atoms, more preferably from 1 to 20 carbon atoms, and especially preferably from 1 to 12 carbon atoms, examples of which include pyridyloxy, pyrazyloxy, pyrimidyloxy, and quinolyloxy), an alkylthio ligand (having preferably from 1 to 30 carbon atoms, more preferably from 1 to 20 carbon atoms, and especially preferably from 1 to 12 carbon atoms, examples of which include methylthio and ethylthio), an arylthio ligand (having preferably from 6 to 30 carbon atoms, more preferably from 6 to 20 carbon atoms, and especially preferably from 6 to 12 carbon atoms, examples of which include phenylthio), a heterocyclic substituted thio ligand (having preferably from 1 to 30 carbon atoms, more preferably from 1 to 20 carbon atoms, and especially preferably from 1 to 12 carbon atoms, examples of which include pyridylthio, 2-benzimidazolylthio, 2-benzoxazolylthio, and 2-benzothiazolylthio), or a siloxy ligand (having preferably from 1 to 30 carbon atoms, more preferably from 3 to 25 carbon atoms, and especially preferably from 6 to 20 carbon atoms, examples of which include a triphenyloxy group, a triethoxysiloxy group, and a triisopropylsiloxy group); more preferably a nitrogen-containing heterocyclic ligand, an aryloxy ligand, an aromatic heterocyclic oxy ligand, or a siloxy ligand; and further preferably a nitrogen-containing heterocyclic ligand, an aryloxy ligand, or a siloxy ligand.

The case containing a photoelectric conversion layer (photosensitive layer) having a p-type semiconductor layer and an n-type sem conductor layer between a pair of electrodes, with at least one of the p-type semiconductor layer and the n-type semiconductor layer being an organic semiconductor, and a bulk heterojunction structure layer containing the p-type semiconductor and the n-type semiconductor as an interlayer between these semiconductor layers is preferable. In such case, in the photoelectric conversion layer, by containing a bulk heterojunction structure in the organic layer, a drawback that the organic layer has a short carrier diffusion length is compensated, thereby improving the photoelectric conversion efficiency. Incidentally, the bulk heterojunction structure is described in detail in Japanese Patent Application No. 2004-080639.

The case where a photoelectric conversion layer (photosensitive layer) having a structure having the number of a repeating structure (tandem structure) of a pn junction layer formed of the p-type semiconductor layer and the n-type semiconductor layer is contained between a pair of electrodes of 2 or more is preferable; and the case where a thin layer made of a conducting material is inserted between the foregoing repeating structures is more preferable. The number of the repeating structure (tandem structure) of a pn junction layer is not limited. For the purpose of enhancing the photoelectric conversion efficiency, the number of the repeating structure (tandem structure) of a pn junction layer is preferably from 2 to 50, more preferably from 2 to 30, and especially preferably from 2 to 10. The conducting material is preferably silver or gold, and most preferably silver. Incidentally, the tandem structure is described in detail in Japanese Patent Application No. 2004-079930.

In the photoelectric conversion layer having a layer of a p-type semiconductor and a layer of an n-type semiconductor (preferably a mixed or dispersed (bulk heterojunction structure) layer) between a pair of electrodes, the case of a photoelectric conversion layer which is characterized by containing an orientation-controlled organic compound in at least one of the p-type semiconductor and the n-type semi-conductor is preferable; and the case of a photoelectric conversion layer which is characterized by containing an orientation-controlled (orientation controllable) organic compound in both the p-type semiconductor and the n-type semiconductor is more preferable. As the organic compound which is used in the organic layer of the photoelectric conversion device, an organic compound having a π-conjugated electron is preferably used. The π-electron plane is not vertical to a substrate (electrode substrate) and is oriented at an angle close to parallel to the substrate as far as possible. The angle against the substrate is preferably 0° or more and not more than 80°, more preferably 0° or more and no: more than 60°, further preferably 0° or more and not more than 40°, still further preferably 0° or more and not more than 20°, especially preferably 0° or more and not more than 10°, and most preferably 0° (namely, in parallel to the substrate). As described previously, it is only required that even a part of the layer of the orientation-controlled organic compound is contained over the whole of the organic layer. A proportion of the orientation-controlled portion to the whole of the organic layer is preferably 10% or more, more preferably 30% or more, further preferably 50% or more, still further preferably 70% or more, especially preferably 90% or more, and most preferably 100%. In the photoelectric conversion layer, by controlling the orientation of the organic compound of the organic layer, the foregoing state compensates a drawback that the organic layer in the photoelectric conversion layer has a short carrier diffusion length, thereby improving the photoelectric conversion efficiency.

In the case where the orientation of an organic compound is controlled, it is more preferable that the heterojunction plane (for example, a pn junction plane) is not in parallel to a substrate. In this case, it is preferable that the heterojunction plane is not in parallel to the substrate (electrode substrate) but is oriented at an angle close to verticality to the substrate as far as position. The angle to the substrate is preferable 0° or more and not more than 90°, more preferably 30° or more and not more than 90°, further preferably 50° or more and not more than 90°, still further preferably 70° or more and not more than 90°, especially preferably 80° or more and not more than 90°, and most preferably 90° (namely, vertical to the substrate). As described previously, it is only required that even a part of the layer of the heterojunction plane-controlled organic compound is contained over the whole of the organic layer. A proportion of the orientation-controlled portion to the whole of the organic layer is preferably 10% or more, more preferably 30% or more, further preferably 50% or more, still further preferably 70% or more, especially preferably 90% or more, and most preferably 100%. In such case, the area of the heterojunction plane in the organic layer increases and the amount of a carrier such as an electron as formed on the interface, a hole, and a pair of an electron and a hole increases so that it is possible to improve the photoelectric conversion efficiency. In the light of the above, in the photoelectric conversion layer in which the orientation of the organic compound on both the heterojunction plane and the π-electron plane is controlled, it is possible to improve especially the photoelectric conversion efficiency. These states are described in detail in Japanese Patent Application No. 2004-079931.

From the standpoint of optical absorption, it is preferable that the layer thickness of the organic dye layer is as thick as possible. However, taking into consideration a proportion which does not contribute to the charge separation, the layer thickness of the organic dye layer in the invention is preferably 30 nm or more and not more than 300 nm, more preferably 50 nm or more and not more than 250 nm and especially preferably 80 nm or more and not more than 200 nm.

(Formation Method of Organic Layer)

A layer containing such an organic compound is subjected to film formation by a dry film formation method or a wet film formation method. Specific examples of the dry film formation method include physical vapor phase epitaxy methods such as a vacuum vapor deposition method, a sputtering method, an ion plating method, and an MBE method and CVD methods such as plasma polymerization. Examples of the wet film formation method include a casting method, a spin coating method, a dipping method, and an LB method.

In the case of using a high molecular compound in at least one of the p-type semiconductor (compound) and the n-type semiconductor (compound), it is preferable that the film formation is achieved by a wet film formation method which is easy for the preparation. In the case of employing a dry film formation method such as vapor deposition, the use of a high molecular compound is difficult because of possible occurrence of decomposition. Accordingly, its oligomer can be preferably used instead of that. On the other hand, in the case of using a low molecular compound, a dry film formation method is preferably employed, and a vacuum vapor deposition method is especially preferably employed. In the vacuum vapor deposition method, a method for heating a compound such as a resistance heating vapor deposition method and an electron beam heating vapor deposition method, the shape of a vapor deposition source such as a crucible and a boat, a degree of vacuum, a vapor deposition temperature, a substrate temperature, a vapor deposition rate, and the like are a basic parameter. In order to achieve uniform vapor deposition, it is preferable that the vapor deposition is carried out while rotating the substrate. A high degree of vacuum is preferable. The vacuum vapor deposition is carried out at a degree of vacuum of not more than 10⁻² Pa, preferably not more than 10⁻⁴ Pa) and especially preferably not more than 10⁻⁶ Pa. It is preferable that all steps at the time of vapor deposition are carried out in vacuo. Basically, the vacuum vapor position is carried out in such a manner that the compound does not come into direct contact with the external oxygen and moisture The foregoing conditions of the vacuum vapor deposition must be strictly controlled because they affect crystallinity, amorphous properties, density, compactness, ans so on. It is preferably employed to subject the vapor deposition rate to PI or PID control using a layer thickness monitor such as a quartz oscillator and an interferometer. In the case of vapor depositing two or more kinds of compounds at the same time, a co-vapor deposition method, a flash vapor deposition method and so on can be preferably employed.

(Electrode)

(Transparent Electrode)

The electromagnetic wave absorption/photo-electric conversion site made of an organic layer is interposed between a pair of electrodes, and at least one of the lower electrode and the upper electrode is a transparent electrode (an electrode having a visible region light transmittance of 80% or more). Further, it is preferable that the pair of electrodes form a pixel electrode and a counter electrode, respectively. It is preferable that the lower layer is a pixel electrode.

It is preferable that the counter electrode extracts a hole from a hole transport photoelectric conversion layer or a hole transport layer. As the counter electrode, a metal, an alloy a metal oxide, an electrically conducting compound, or a mixture thereof can be used. It is preferable that the pixel electrode extracts an electron from an electron transport photoelectric conversion layer or an electron transport layer. The pixel electrode is selected while taking into consideration adhesion to an adjacent layer such as an electron transport photoelectric conversion layer and an electron transport layer, electron affinity, ionization potential, stability, and the like. Specific examples thereof include conducting metal oxides such as tin oxide, zinc oxide, indium oxide, and indium tin oxide (ITO); metals such as gold, silver chromium, and nickel; mixtures or stacks of such a metal and such a conducting metal oxide; inorganic conducting substances such as copper iodide and copper sulfide; organic conducting materials such as polyaniline, polythiophene, and polypyrrole; silicon compounds; and stack materials thereof with ITO. Of these, conducting metal oxides are preferable; and ITO and IZO (indium zinc oxide) are especially preferable in view of productivity, high conductivity, transparency, and so on. Though the layer thickness can be properly selected depending upon the material in general, it is preferably in the range of 10 nm or more and not more than 1 μm, more preferably in the range of 30 nm or more and not more than 500 nm, and further preferably in the range of 50 nm or more and not more than 300 nm.

In the preparation of the pixel electrode and the counter electrode, various methods are employable depending upon the material. For example, in the case of ITO, the layer is formed by a method such as an electron beam method, a sputtering method, a resistance heating vapor deposition method, a chemical reaction method (for example, a sol-gel method), and coating of a dispersion of indium tin oxide. In the case of ITO, a UV-ozone treatment, a plasma treatment, or the like can be applied.

It is preferable that a transparent electrode layer is prepared in a plasma-free state. By preparing a transparent electrode layer in a plasma-free state, it is possible to minimize influences of the plasma against the substrate and to make photoelectric conversion characteristics satisfactory. Here, the term “plasma-free state” means a state that plasma is not generated during the film formation of a transparent electrode layer or that a distance from the plasma generation source to the substrate is 2 cm or more, preferably 10 cm or more, and more preferably 20 cm or more and that the plasma which reaches the substrate is reduced.

Examples of a device in which plasma is not generated during the film formation of a transparent electrode layer include an electron beam vapor deposition device (EB vapor deposition device) and a pulse laser vapor deposition device. With respect to the EB vapor deposition device or pulse laser vapor deposition device, devices as described in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein can be used. In the following, the method for achieving film formation of a transparent electrode film using an Et vapor deposition device is referred to as “EB vapor deposition method”; and the method for achieving film formation of a transparent electrode film using a pulse laser vapor deposition device is referred to as “pulse laser vapor deposition method”.

With respect to the device capable of realizing the state that a distance from the plasma generation source to the substrate is 2 cm or more and that the plasma which reaches the substrate is reduced (hereinafter referred to as “plasma-free film formation device”), for example, a counter target type sputtering device and an arc plasma vapor deposition method can be thought. With respect to these matters, devices as described in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein can be used.

The electrode of the organic electromagnetic wave absorption/photoelectric conversion site will be hereunder described in more detail. The photoelectric conversion layer as an organic layer is interposed between a pixel electrode layer and a counter electrode layer and can contain an interelectrode material or the like. The “pixel electrode layer” as referred to herein refers to an electrode layer as prepared above a substrate in which a charge storage/transfer/read-out site is formed and is usually divided for every one pixel. This is made for the purpose of obtaining an image by reading out a signal charge which has been converted by the photoelectric conversion, layer on a charge storage/transfer/signal read-out circuit substrate for every one pixel.

The “counter electrode layer” as referred to herein has a function to discharge a signal charge having a reversed polarity to a signal charge by interposing the photoelectric conversion layer together with the pixel electrode layer. Since this discharge of a signal charge is not required to be divided among the respective pixels, the counter electrode layer can be usually made common among the respective pixels. For that reason, the counter electrode layer is sometimes called a common electrode layer.

The photoelectric conversion layer is positioned between the pixel electrode layer and the counter electrode layer. The photoelectric conversion function functions by this photoelectric convention layer and the pixel electrode layer and the counter electrode layer.

As examples of the configuration of the photoelectric conversion layer stack, first of all, in the case where one organic layer is stacked on a substrate, there is enumerated a construction in which a pixel electrode layer (basically a transparent electrode layer), a photoelectric conversion layer and a counter electrode layer (transparent electrode layer) are stacked in this order from the substrate. However, it should not be construed that the invention is limited thereto.

In addition, in the case where two organic layers are stacked on a substrate, there is enumerated a construction in which a pixel electrode layer (basically a transparent electrode layer), a photoelectric conversion layer, a counter electrode layer (transparent electrode layer), an interlaminar insulating layer, a pixel electrode layer (basically a transparent electrode layer), a photoelectric conversion layer, and a counter electrode layer (transparent electrode layer) are stacked in this order from the substrate.

As the material of the transparent electrode layer which configures the photoelectric conversion site, materials which can be subjected to film formation by a plasma-free film formation device, EB vapor deposition device or pulse laser vapor deposition device. For example, metals, alloys, metal oxides, metal nitrides, metallic borides, organic conducting compounds, and mixtures thereof can be suitably enumerated. Specific examples thereof include conducting metal oxides such as tin oxide, zinc oxide, indium oxide, indium zinc oxide (IZO), indium tin oxide (ITO), and indium tungsten oxide (IWO); metal nitrides such as titanium nitride; metals such as gold, platinum, silver, chromium, nickel and aluminum; mixtures or stacks of such a metal and such a conducting metal oxide; inorganic conducting substances such as copper iodide and copper sulfide; organic conducting materials such as polyaniline, polythiophene, and polypyrrole; and stacks thereof with ITO. Also, materials as described in detail in Developments of Transparent Conducting Films, supervised by Yutaka Sawada (published by CMC Publishing Co., Ltd., 1999); Developments of Transparent Conducting Films II, supervised by Yutaka Sawada (published by CMC Publishing Co., Ltd., 2002); Technologies of Transparent Conducting Films, written by Japan Society for the Promotion of Science (published by Ohmsha, Ltd., 1999); and references as added therein may be used.

As the material of the transparent electrode layer, any one material of ITO, IZO, SnO₂, ATO (antimony-doped tin oxide), ZnO, AZO (Al-doped zinc oxide), GZO (gallium-doped zinc oxide), TiO₂, or FTO (fluorine-doped tin oxide) is especially preferable.

A light transmittance of the transparent electrode layer is preferably 60% or more, more preferably 80% or more, further preferably 90% or more, and still further preferably 95% or more at a photoelectric conversion optical absorption peak wavelength of the photoelectric conversion layer to be contained in a photoelectric conversion device containing that transparent electrode layer. Furthermore, with respect to a surface resistance of the transparent electrode layer, its preferred range varies depending upon whether the transparent electrode layer is a pixel electrode or a counter electrode, whether the charge storage/transfer/read-out site is of a CCD structure or a CMOS structure, and the like. In the case where the transparent electrode layer is used for a counter electrode and the charge storage/transfer/read-out site is of a CMOS structure, the surface resistance is preferably not more than 10,000 Ω/□ and more preferably not more than 1,000 Ω/□. In the case where the transparent electrode layer is used for a counter electrode and the charge storage/transfer/read-out site is of a CCD structure, the surface resistance is preferably not more than 1,000 Ω/□, and more preferably not more than 100 Ω/□. In the case where the transparent electrode layer is used for a pixel electrode, the surface resistance is preferably not more than 1,000,000 Ω/□, and more preferably not more than 100,000 Ω/□.

Conditions at the time of fabrication of a transparent electrode layer will be hereunder mentioned. A substrate temperature at the time of fabrication of a transparent electrode layer is preferably not higher than 500° C., move preferably not higher than 300° C., further preferably not higher than 200° C., and still further preferably not higher than 150° C. Furthermore, a gas may be introduced during the film formation of a transparent electrode. Basically, though the gas species is act limited, Ar, Be, oxygen, nitrogen, and so or can be used. Furthermore, a mixed gas of such gates may be used. In particular, in the case of an oxide material, since oxygen deficiency often occurs, it is preferred to use oxygen.

The case of applying voltage to the photoelectric conversion layer is preferable in view of improving the photoelectric conversion efficiency. Though any voltage is employable as the voltage to be applied, necessary voltage varies with the layer thickness of the photoelectric conversion layer That is, the larger an electric field to be added in the photo-electric conversion layer, the more improved the photoelectric conversion efficiency is. However, even when the same voltage is applied the thinner the layer thickness of the photoelectric conversion layer, the larger an electric field to be applied is. Accordingly, in the case where the layer thickness of the photoelectric conversion film is thin, the voltage to be applied may be relatively small. The electric field to be applied to the photoelectric conversion layer is preferably 10 V/cm or more, more preferably 1×10³ V/cm or more, further preferably 1×10⁵ V/cm or more, especially preferably 1×10⁶ V/cm or more, and most preferably 1×10⁷ V/cm or more. Though there is no particular upper limit, when the electric field is excessively applied, an electric current flows even in a dark place and therefore, such is not preferable. The electric field is preferably not more than 1×10¹² V/cm, and more preferably not more than 1×10⁹ V/cm.

(Stack Type Photoelectric Conversion Device)

The layer of the organic photoelectric conversion device of the invention can be formed into a stack type photoelectric conversion device by stacking with other photoelectric conversion device layer.

The stack type photoelectric conversion device will be hereunder described.

The photoelectric conversion device is comprised of an electromagnetic wave absorption/photoelectric conversion site and a charge storage of charge as generated by photoelectric conversion/transfer/and read-out site.

The electromagnetic wave absorption/photoelectric conversion site has a stack type structure made of at least two layers, which is capable of absorbing each of blue light, green light and red light and undergoing photoelectric conversion. A blue light absorbing layer (B) is able to absorb at least light of from 400 to 500 nm and preferably has an absorptance of a peak wavelength in that wavelength region of 50% or more. A green light absorbing layer (G) is able to absorb at least light of from 500 to 600 nm and preferably has an absorptance of a peak wavelength in that wavelength region of 50% or more. A red light absorbing layer (R) is able to absorb at least light of from 600 to 700 nm and preferably has an absorptance of a peak wavelength in that wavelength region of 50% or more. The order of these layers is not limited. In the case of a three-layer stack type structure, orders of BGR, BRG, GBR, GRB, RBG and RGB from the upper layer (light incident side) are possible. It is preferable that the uppermost layer is G. In the case of a two-layer stack type structure, when the upper layer is an R layer, a BG layer is formed as the lover layer in the same planar state; when the upper layer is a B layer, a GR layer is formed as the lower layer in the same planar state; and when the upper layer is a G layer, a BR layer is formed as the lower layer in the same planar state. It is preferable that the upper layer is a G layer and the lower layer is a BR layer in the same planar state. In the case where two light absorbing layers are provided in the same planar state of the lower layer in this way, it is preferable that a filter layer capable of undergoing color separation is provided in, for example, a mosaic state on the upper layer or between the upper layer and the lower layer. Under some circumstances, it is possible to provide a fourth or polynomial layer as a new layer or in the same planar state.

The charge storage/transfer/read-out site is provided under the electromagnetic wave absorption/photoelectric conversion site. It is preferable that the electromagnetic wave absorption/photoelectric conversion site which is the lower layer also serves as the charge storage/transfer/read-out site.

The electromagnetic wave absorption/photoelectric conversion site is made of an organic layer or an inorganic layer or a mixture of an organic layer and an inorganic layer. The organic layer may form a B/G/R layer or the inorganic layer may form a B/G/R layer. It is preferable that the electromagnetic wave absorption/photoelectric conversion site is made of a mixture of an organic layer and an inorganic layer. In this case, basically, when the organic layer is made of a single layer, the inorganic layer is made of a single layer or two layers; and when the organic layer is made of two layers, the inorganic layer is made of a single layer. When each of the organic layer and the inorganic layer is made of a single layer, the inorganic layer forms an electromagnetic wave absorption/photoelectric conversion site of two or more colors in the same planar state. It is preferable that the upper layer is made of an organic layer which is constructed of a G layer and the lower layer is made of an inorganic layer which is constructed of a B layer and an R layer in this order from the upper side. Under some circumstances, it is possible to provide a fourth or polynomial layer as a new layer or in the same planar state. When the organic layer forms a B/G/R layer, a charge storage/transfer/read-out site is provided thereunder. When an inorganic layer is used as the electromagnetic wave absorption/photoelectric conversion site, this inorganic layer also serves as the charge storage/transfer/read-out site.

(Inorganic Layer)

An inorganic layer as the electromagnetic wave absorption/photoelectric conversion site will be hereunder described. In this case, light which has passed through the organic layer as the upper layer is subjected to photoelectric conversion in the inorganic layer. With respect to the inorganic layer, pn junction or pin junction of crystalline silicon, amorphous silicon, or a chemical semiconductor such as GaAs is generally employed. With respect to the stack type structure, a method as disclosed in U.S. Pat. No. 5,965,875 can be employed. That is, a construction in which a light receiving part as stacked by utilizing wavelength dependency of a coefficient of absorption of silicon is formed and color separation is carried out in a depth direction thereof. In this case, since the color separation is carried out with a light penetration depth of silicon, a spectrum range as received in each of the stacked light receiving parts becomes broad. However, by using the foregoing organic layer as the upper layer, namely by detecting the light which has transmitted through the organic layer in the depth direction of silicon, the color separation is remarkably improved. In particular, when a G layer is disposed in the organic layer, since light which has transmitted through the organic layer is B light and R light, only BR light is subjective to separation of light in the depth direction in silicon so that the color separation is improved. Even in the case where the organic layer is a B layer or an R layer, by properly selecting the electromagnetic wave absorption/photoelectric conversion site of silicon in the depth direction, the color separation is remarkably improved. In the case where the organic layer is made of two layers, the function as the electromagnetic wave absorption/photoelectric conversion site of silicon may be brought for only one color, and preferred color separation can be achieved.

The inorganic layer preferably has a structure in which plural photodiodes are superposed for every pixel in a depth direction within the semiconductor substrate and a color signal corresponding to a signal charge as generated in each of the photodiodes by light as absorbed in the plural photodiodes is read out into the external. It is preferable that the plural photodiodes contain a first photodiode as provided in the depth for absorbing B light and at least one second photodiode as provided in the depth for absorbing R light and are provided with a color signal read-out circuit for reading out a color signal corresponding to the foregoing signal charge as generated in each of the foregoing plural photodiodes. According to this construction, it is possible to carry out color separation without using a color filter. Furthermore, according to circumstances, since light of a negative sensitive component can also be received, it becomes possible to realize color imaging with good color reproducibility. Moreover, in the invention, it is, preferable that a junction part of the foregoing first photodiode is formed in a depth of up to about 0.2 μm from the semiconductor substrate surface and that a junction part of the foregoing second photodiode is formed in a depth of up to about 2 μm from the semiconductor substrate surface.

The inorganic layer will be hereunder described in more detail. Preferred examples of the construction of the inorganic layer include a photoconductive type, a p-n junction type, a shotkey junction type, a PIN junction type, a light receiving device of MSM (metal-semiconductor-metal) type, and a light receiving device of phototransistor type. In the invention, it is preferred to use a light receiving device in which a plural number of a first conducting type region and a second conducting type region which is a reversed conducting type to the first conducting type are alternately stacked within a single semiconductor substrate and each of the junction planes of the first conducting type and second conducting type regions is formed in a depth suitable for subjecting mainly plural lights of a different wavelength region to photoelectric conversion. The single semiconductor substrate is preferably mono-crystalline silicon, and the color separation can be carried out by utilizing absorption wavelength characteristics relying upon the depth direction of the silicon substrate.

As the inorganic semiconductor, InGaN based, InAlN based, InAlP based, or InGaAlP based inorganic semiconductors can also be used. The InGaN based inorganic semiconductor is an inorganic semiconductor as adjusted so as to have a maximum absorption value within a blue wavelength range by properly changing the In-containing composition. That is, the composition becomes InₓGa₁₋ₓN (0≦<1). Such a compound semiconductor is produced by employing a metal organic chemical vapor deposition on method (MOCVD method). With respect to the InAlN based nitride semi-conductor using, as a raw material, Al of the Group 13 similar to Ga, it can be used as a short wavelength light receiving part similar to the InGaN based semiconductor. Furthermore, InAlP or InGaAlP lattice-matching with a GaAs substrate can also be used.

The inorganic semiconductor may be of a buried structure. The “buried structure” as referred to herein refers to a construction in which the both ends of a short wavelength light receiving part are covered by a semiconductor different from the short wavelength light receiving part. The semiconductor for covering the both ends is preferably a semiconductor having a band gap wavelength shorter than or equal to a hand gap wavelength of the short wavelength light receiving part.

The organic layer and the inorganic layer may be bound to each other in any form.

Furthermore, for the purpose of electrically insulating the organic layer and the inorganic layer from each other, it is preferred to provide an insulating layer therebetween.

With respect to the junction, npn junction or pnpn junction from the light incident side is preferable. In particular, the pnpn junction is more preferable because by providing a p layer on the surface and increasing a potential of the surface it is possible to trap a hole as generated in the vicinity of the surface and a dark current and reduce the dark current.

In such a photodiode, when an n-type layer, a p-type layer, an n-type layer and a p-type layer which are successively diffused from the p-type silicon substrate surface are deeply formed in this order, the pn-junction diode is formed of four layers of pnpn in a depth direction of silicon. With respect to the light which has come into the diode from the surface side, the longer the wavelength, the deeper the light penetration is. Also, the incident wavelength and the attenuation coefficient are inherent to silicon. Accordingly, the photodiode is designed such that the depth of the pn junction plane covers respective wavelength bands of visible light. Similarly, a junction diode of three layers of npn is obtained by forming an n-type layer, a p-type layer and n-type layer in this order. Here, a light signal is extracted from the n-type layer, and the p-type layer is connected to a ground wire.

Furthermore, when an extraction electrode is provided in each region and a prescribed reset potential is applied, each region is depleted, and the capacity of each junction part becomes small unlimitedly. In this way, it is possible to make the capacity as generated on the junction plane extremely small.

(Auxiliary Layer)

It is preferred to provide an ultraviolet light absorption layer and/or an infrared light absorption layer as an uppermost layer of the electromagnetic wave absorption/photoelectric conversion site. The ultraviolet light absorption layer is able to at least absorb or reflect light of not more than 400 nm and preferably has an absorptance of 50% or more in a wavelength region of not more that 400 nm. The infrared light absorption layer is able to at least absorb or reflect light of 700 nm or more and preferably has an absorptance of 50% or more in a wavelength region of 700 nm or more.

Such an ultraviolet light absorption layer or infrared light absorption layer can be formed by a conventionally known method. For example, there is known a method in which a mordant layer made of a hydrophilic high molecular substance such as gelatin, casein, glue, and polyvinyl alcohol is provided on a substrate and a dye having a desired absorption wavelength is added to or dyes the mordant layer to form a colored layer. In addition, there is known a method of using a colored resin resulting from dispersing a certain kind of coloring material in a transparent resin. For example, it is possible to use a colored resin layer resulting from mixing a coloring material in a polyamino based resin as described in JP-A-58-46325, JP-A-60-78401, JP-A-60-184202, JP-A-60-184203, JP-A-60-184204, and JP-A-60-184205. A coloring agent using a polyamide resin having photosensitivity can also be used.

It is also possible to disperse a coloring material in an aromatic polyamide resin containing a photosensitive group in the molecule thereof and capable of obtaining a cured layer at not higher than 200° C. as described in JP-B-7-113685 and to use a colored resin having a pigment dispersed therein as described in JP-B-7-69486.

A dielectric multiple layer is preferably used. The dielectric multiple layer has sharp wavelength dependency of light transmission and is preferably used.

It is preferable that the respective electro-magnetic wave absorption/photoelectric conversion sites are separated by an insulating layer. The insulating layer can be formed by using a transparent insulating material such as glass, polyethylene, polyethylene terephthalate, polyethersulfone, and polypropylene. Silicon nitride, silicon oxide, and the like are also preferably used. Silicon nitride prepared by film formation by plasma CVD is preferably used in the invention because it is high in compactness and good in transparency.

For the purpose of preventing contact with oxygen, moisture, etc., a protective layer of a sealing layer can be provided, too. Examples of the protective layer include a diamond thin layer, an inorganic material layer made of a metal oxide, a metal nitride, etc., a high molecular layer made of a fluorine resin, poly-p-xylene, polyethylene, a silicone resin, a polystyrene resin, etc., and a layer made of a photocurable resin. Furthermore, it is also possible to cover a device portion by glass, a gas-impermeable plastic, a metal, etc. and package the device itself by a suitable sealing resin. In this case, it is also possible to make a substance having high water absorption properties present in a packaging.

In addition, light collecting efficiency can be improved by forming a microlens array in the upper part of a light receiving device, and therefore, such an embodiment is preferable, too.

(Charge Storage/Transfer/Read-Out Site)

As to the charge storage/transfer/read-out site, JP-A-58-103166, JP-A-58-103165, JP-A-2003-332551, and so on can be made hereof by reference. A construction in which an MOS transistor is formed on a semiconductor substrate for every pixel unit or a construction having CCD as a device can be properly employed. For example, in the case of a photoelectric conversion device using an MOS transistor, a charge is generated in a photoelectric conversion layer by incident light which has transmitted through electrodes; the charge runs to the electrodes within the photoelectric conversion layer by an electric field as generated between the electrodes by applying voltage to the electrodes; and the charge is further transferred to a charge storage part of the MOS transistor and stored in the charge storage part. The charge as stored in the charge storage part is transferred to a charge read-out part by switching of the MOS transistor and further outputted as an electric signal. In this way, full-color image signals are inputted in a solid-state imaging device including a signal processing part.

The signal charge can be read out by injecting a fixed amount of bias charge into the storage diode (refresh mode) and then storing a fixed amount of the charge (photoelectric conversion mode). The light receiving device itself can be used as the storage diode, or an storage diode can be separately provided.

The read-out of the signal will be hereunder described in more detail. The read-out of the signal can be carried out by using a usual color read-out circuit. A signal charge or a signal current which is subjected to light/electric conversion in the light receiving part is stored in the light receiving part itself or a capacitor as provided. The stored charge is subjected to selection of a pixel position and read-out by a measure of an MOS type imaging device (so-called CMOS sensor) using an X-Y address system. Besides, as an address selection system, there is enumerated a system in which every pixel is successively selected by a multiplexer switch and a digital shift register and read out as a signal voltage (or charge) on a common output line. An imaging device of a two-dimensionally arrayed X-Y address operation is known as a CMOS sensor. In this imaging device, a switch as provided in a pixel connected to an X-Y intersection point is connected to a vertical shift register, and when the switch is turned on by a voltage from the vertical scanning shift register, signals as read out from pixels as provided in the same line is read out on the output line in a column direction. The signals are successively read out from an output end through the switch to be driven by a horizontal scanning shift register.

For reading out the output signals, a floating diffusion detector or a floating gate detector can be used. Furthermore, it is possible to seek improvements of S/N by a measure such as provision of a signal amplification circuit in the pixel portion and correlated double sampling.

For the signal processing, gamma correction by an ADC circuit, digitalization by an AD transducer, luminance signal processing, and color signal processing can be applied. Examples of the color signal processing include white balance processing, color separation processing, and color matrix processing. In using for an NTSC signal, an RGB signal can be subjected to conversion processing of a YIQ signal.

The charge transfer/read-out site must have a mobility of charge of 100 cm²/vol·sec or more. This mobility can be obtained by selecting the material among semiconductors of the IV group, the III-V group or the II-VI group. Above all, silicon semiconductors (also referred to as “Si semiconductor”) are preferable because of advancement of microstructure refinement technology and low costs. As to the charge transfer/charge read-out system, there are made a number of proposals, and all of them are employable. Above all, a COMS type device or a CCD type device is an especially preferred system. In addition, in the case of the invention, in many occasions, the CMOS type device is preferable in view of high-speed read-out, pixel addition, partial read-out and consumed electricity.

(Connection)

Though plural contact sites fox connecting the electromagnetic wave absorption/photoelectric conversion side to the charge transfer/read-out site may be connected by any metal, a metal selected among copper, aluminum, silver, gold, chromium and tungsten is preferable, and copper is especially preferable. In response to the plural electromagnetic wave absorption/photoelectric conversion sites, each of the contact sites must be placed between the electromagnetic wave absorption/photoelectric conversion site and the charge transfer/read-out site. In the case of employing a stacked structure of plural photosensitive units of blue, green and red lights, a blue light extraction electrode and the charge transfer/read-out site, a green light extraction electrode and the charge transfer/read-out site, and a red light extraction electrode and the charge transfer/read-out site must be connected, respectively.

(Process)

The stacked photoelectric conversion device of the invention can be produced according to a so-called known microfabrication process which is employed in manufacturing integrated circuits and the like. Basically, this process is concerned with a repeated operation of pattern exposure with active light, electron beams, etc. (for example, i- or g-bright line of mercury, excimer laser, X-rays, and electron beams), pattern formation by development and/or burning, alignment of device forming materials (for example, coating, vapor deposition, sputtering, and CV), and removal of the materials in a non-pattern area (for example, heat treatment and dissolution treatment).

(Utility)

A chip size of the device can be selected among a brownie size, a 135 size, an APS size, a 1/1.8-inch size, and a smaller size. A pixel size of the stacked photoelectric conversion device of the invention is expressed by a circle-corresponding diameter which is corresponding to a maximum area in the plural electromagnetic absorption/photoelectric conversion sites. Though the pixel size is not limited, it is preferably from 2 to 20 microns, more preferably from 2 to 10 microns, and especially preferably from 3 to 8 microns.

When the pixel size exceeds 20 microns, a resolving power is lowered, whereas when the pixel size is smaller than 2 microns, the resolving power is also lowered due to radio interference between the sizes.

The stack type photoelectric conversion device can be utilized for a digital still camera. Also, it is preferable that the photoelectric conversion device of the invention is used for a TV camera. Besides, the photoelectric conversion device of the invention can be utilized for a digital video camera, a monitor camera (in, for example, office buildings, parking lots, unmanned loan-application systems in financial institution, shopping centers, convenience stores, outlet malls, department stores, pachinko parlors, karaoke boxes, game centers and hospitals) other various sensors (for example, TH door intercoms, individual authentication sensors, sensors for factory automation, robots for household use, industrial robots, and piping examination systems), medical sensors (for example, endoscopes and fundus cameras), videoconference systems, television telephones, camera-equipped mobile phones, automobile safety running systems (for example, back guide monitors, collision prediction systems, and lane-keeping systems), and sensors for video game.

Above all, the stack type photoelectric conversion device is suitable for use of a television camera. The reason for this resides in the matter that since it does not require a color decomposition optical system, it is able to achieve miniaturization and weight reduction of the television camera. Furthermore, since the photoelectric conversion device of the invention has high sensitivity and high resolving power, it is especially preferable for a television camera for high-definition broadcast. In this case, the term “television camera for high-definition broadcast” as referred to herein includes a camera for digital high-definition broadcast.

In addition, the stack type photoelectric conversion device is preferable because an optical low pass filter can be omitted and higher sensitivity and higher resolving power can be expected.

In addition, in the stack type photoelectric conversion device, not only the thickness can be made thin, but also a color decomposition optical system is not required. Therefore, with respect to shooting scenes in which a different sensitivity is required, such as “circumstances with a different brightness such as daytime and nighttime” and “immobile subject and mobile subject” and other shooting scenes in which requirements for spectral sensitivity or color reproducibility differ, various needs for shooting can be satisfied by a single camera by exchanging the photoelectric conversion device of the invention and performing shooting. At the same time, it is not required to carry plural cameras. Thus, a load of a person who wishes to take a shot is reduced. As a photoelectric conversion device which is subjective to the exchange, in addition to the foregoing, exchangeable photoelectric conversion devices for purposes of infrared light shooting, black-and-white shooting, and change of a dynamic range can be prepared.

The TV camera of the invention can be prepared by referring to a description in Chapter 2 of Design Technologies of Television Camera, edited by the Institute of Image Information and Television Engineers (Aug. 20, 1999, published by Corona Publishing Co., Ltd., ISBN 4-339-00714-5) and, for example, replacing a color decomposition optical system and an imaging device as a basic construction of a television camera as shown in FIG. 2.1 thereof by the photoelectric conversion device of the invention.

By aligning the foregoing stacked light receiving device, it can be utilized not only as an imaging device but also as an optical sensor such as biosensors and chemical sensors or a color light receiving device in a single body.

### EXAMPLES

The invention will be described below with reference to the following Examples, but it should not be construed that the invention is limited thereto.

### Comparative Example 1

### FIG. 1A

With respect to a structure in which 100 nm-thick quinacridone (the following Compound 1:5,12-dihydro-quino[2,3-b]acridine-7,14-dione) and a 100 nm-thick Al upper electrode (work function: 4.3 eV as determined by an atmospheric photoelectron spectrometer AC-2, manufactured by Riken Keiki Co., Ltd.; visible region light transmittance: 0%) are successively stacked on a glass substrate (a commercially available product) having a 250 nm-thick ITO lower electrode (work function: 4.8 eV; visible region light transmittance: about 90%) stacked thereon by vacuum vapor deposition, there is exemplified the case where an electron is collected in the side of the ITO lower electrode. A device (device area: 2 mm×2 mm) was actually prepared and measured. As a result, a dark current at the applied voltage of 1 V (an electron was collected using the lower electrode as a positive bias; hereinafter the same) was a large value as 9.3 μA/cm².

In this case, as illustrated in FIG. 1A, it is thought that since the work function of ITO as an electron collecting electrode is large, the hole injection from the ITO electrode into the quinacridone is easy to occur when bias voltage is applied so that the dark current becomes large.

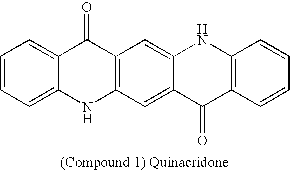

### Example 1

### FIG. 1B

On the other hand, a device was prepared in the same manner as in Comparative Example 1, except for using, as the lower electrode, an electrode as prepared by stacking In having a small work function as 4.3 eV in a thickness of 2 nm on in ITO electrode by vacuum vapor deposition (visible light transmittance of 2 nm-thick In: about 98%). As a result, the dark current at the applied voltage of 1 V is largely reduced to 1.8 nA/cm² a value of which is lowered by approximately four digits.

As illustrated in FIG. 1B, this means that the hole injection from the electron collecting electrode is largely reduced by making the work function of the lower electrode which is the electron collecting electrode small.

Similarly, light of 550 nm was made incident from the lower ITO side in an irradiation intensity of 50 μW/cm² under a condition of applying bias of 1 V. As a result, the external quantum efficiency (measured charge number against the incident photo number) was 12%. Furthermore, at the applied bias of 2 V, the dark current was about 100 nA/cm², and the external quantum efficiency was 19%.

### Example 2

### FIG. 1C

In addition, a device was prepared in the same manner as in Example 1, except for replacing the upper electrode from the Al electrode to an ITO electrode (work function: 4.8 eV; visible region light transmittance: 98%) to adjust the work function, thereby devising to reduce the dark current and realize a low bias. Here, the ITO transparent electrode as the upper electrode was deposited in thickness of 10 nm on an organic layer at 40 W by means of RF magnetron sputtering. At the time of sputtering film formation of ITO, although some devices caused a short circuit due to damage onto the organic layer, some devices which had been able to be successfully fabricated without causing a short circuit were provided for the measurement. Light of 550 nm was made incident from the lower ITO side in an irradiation intensity of 50 μW/cm². As a result at the applied bias of 2 V, the dark current was 40 nA/cm², and the external quantum efficiency was 42.

In comparison with Example 1, it is thought that more reduction of the dark current (at the bias of 2 V: 100 nA/cm² [symbol] 40 nm/cm²) is resulted from reduction the electron injection, too as illustrated in FIG. 1C. Furthermore, in view of FIGS. 1A to 1C, an improvement in the external quantum efficiency (at the time of a bias of 2 V: 19% [symbol] 42%) can be explained as follows. That is, the bias voltage for applying certain electric field strength to the inside of the organic layer varies depending upon a combination of the upper and lower electrodes. For example, as illustrated in FIGS. 1A to 1C, in the case where in having a work function of 4.3 eV is used as the lower electrode and ITO having a work function of 4.8 eV is used as the upper electrode (FIG. 1C), it is possible to apply electric field strength of the same degree to the inside of the organic layer at a low bias as compared with the case where ITO having a work function of 4.8 eV is used as the lower electrode and Al having a work function of 4.3 eV is used as the upper electrode (FIG. 1A) and the case where In having a work function of 4.3 eV is used as the lower electrode and Al having a work function of 4.3 eV is used as the upper electrode (FIG. 1B). In this way, realization of a low bias can be expected. Actually, in the ITO/In/quinacridone/ITO device as examined herein (FIG. 1C), the external quantum efficiency of 19% is obtained at a bias of 1.5 V, and as compared with the ITO/In/quinacridone/Al device (FIG. 1B), the external quantum efficiency of the same degree is obtained at a low bias.

### Example 3

So far, the results obtained in stacking an In thin layer on an ITO electrode with respect to a device resulting from interposing a quinacridone single layer originally having a large dark current between electrodes have been described. Now, in order to confirm generality, in stacking an In thin layer, too with respect to a device with reduce dark current by a multilayered configuration of an organic material, whether or not the effects are revealed was examined. The configuration of the photoelectric conversion device as examined herein is ITO/BCR (the following Compound 2: 2,9-dimethyl-4,7-diphenyl-1,10-phenathroline) (20 nm)/Alq3 (the following Compound 3: tris(8-hydroxyquinolinato)aluminum(III) complex) (50 nm) /quinacridone (100 nm)/m-MTDATA (the following Compound 4: 4,4′,4″-tris(N-(3-methylphenyl)N-phenylamino)triphenylamine) (5 μnm)/Al (100 nm). When the bias of 10 V was applied to this device, the dark current was 5.6 nA/cm², and the external quantum efficiency in an irradiation intensity of 50 μW/cm² from the ITO side by light of 550 nm was 18%. In the case where a 2 nm-thick In thin layer was stacked on the ITO of this device, the dark current was 670 pA/cm² and the external quantum efficiency was 19% under the same measurement conditions. In this way, with respect to the device with a reduced dark current by the other measure such as organic multilayered configuration, the dark current could be more reduced by approximately one digit.

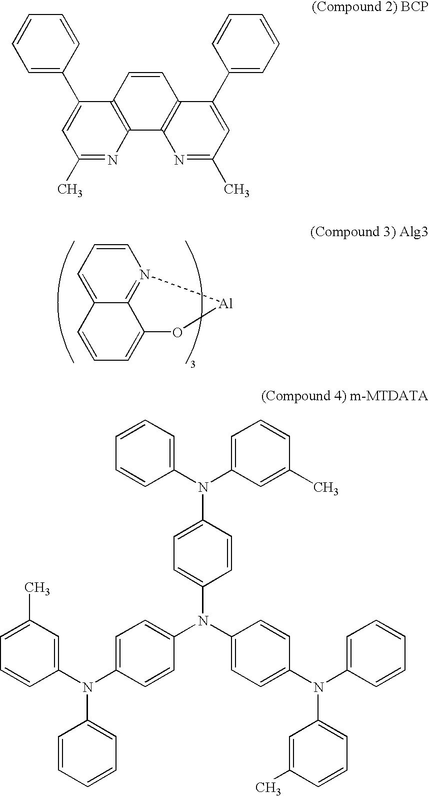

Incidentally, a configuration view of the organic photoelectric conversion device in which the upper electrode and the lower electrode are each made of a transparent electrode is shown in FIG. 2 while referring to Example 2 as an example. In (3) is deposited by vacuum vapor deposition in thickness of 2 nm on a glass substrate (1) (a commercially available product) having a 250 nm-thick ITO electrode (2) stacked thereon. Subsequently, quinacridone (4) which is one of organic semiconductor materials is deposited by vacuum vapor deposition in thickness of 100 nm in the same manner. In addition, an ITO electrode (5) is deposited by sputtering in vacuum in thickness of 10 nm. By this configuration, it is possible to set up the work function of the lower electrode at 4.3 eV and the work function of the upper electrode at 4.8 eV, respectively. Assuming that an electron is collected by the lower electrode and that a hole is collected by the upper electrode, it is possible to reduce both the hole injection and the electron injection from the respective electrodes.

### Example 4

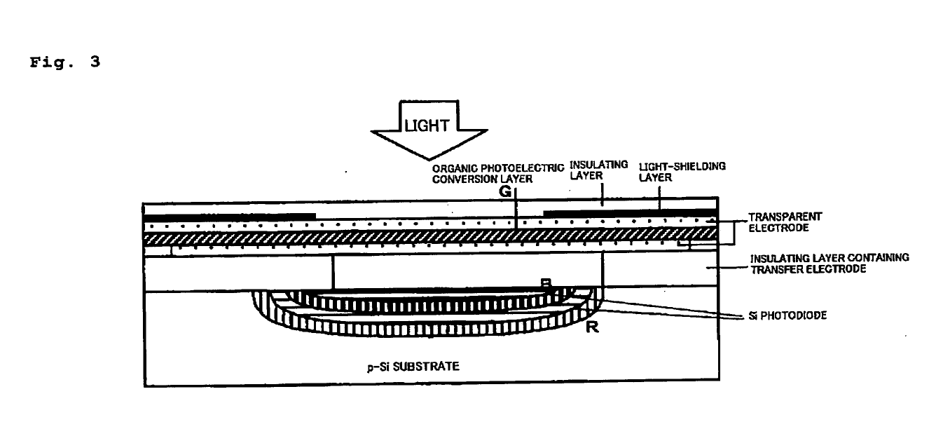

### FIG. 3

As a working example, a structure in which the organic photoelectric conversion device having a configuration as illustrated in FIG. 1C is stacked on an Si substrate including a signal transfer circuit and a photodiode is shown in FIG. 3 (an In layer is not illustrated therein). Quinacridone absorbs green (G) light to cause photoelectric conversion, and transmitted blue (B) light and red (R) light are photoelectrically converted in the photodiode as provided in the lower Si substrate. This photodiode is formed of a plural number of a p-type layer and an n-type layer as superposed on each other, and the depth of each of the junction faces therebetween is formed such that it is suitable for the photoelectric conversion of mainly the respective lights in two blue and red wavelength regions. In this way, it is possible to photoelectrically convert the G light by the upper organic photoelectric conversion layer and the B light and the R light by the photodiode in the lower Si substrate, respectively. Furthermore, since the G light is first absorbed in the upper part, the color separation between B and G lights and between G and R lights is excellent. This is a greatly excellent point as compared with a photoelectric conversion device of a type in which all BGR lights are separated within the Si photodiode in the depth direction.

In such a stack structure, the signal charge as obtained in the upper photoelectric conversion layer is read out through the signal transfer circuit as provided in the Si substrate. While any of the upper electrode and the lower electrode may be connected to the signal transfer circuit, a system of connecting the lower electrode to the signal transfer circuit and reading out the signal charge as collected by the lower electrode is preferable from the viewpoint of process difficulty. Furthermore, examples of the system of the signal transfer circuit in the Si substrate include CCD and CMOS structures. Of these, the CMOS type is preferable in view of consumed electricity, high-speed read-out, pixel addition, partial read-out, and so on. Furthermore, while any of an electron and a hole may be thought as the signal charge which is collected by the electrode as connected to the signal transfer circuit, the electron is preferable in view of the mobility in Si, the degree of completeness of process conditions, and so on.

### Example 5

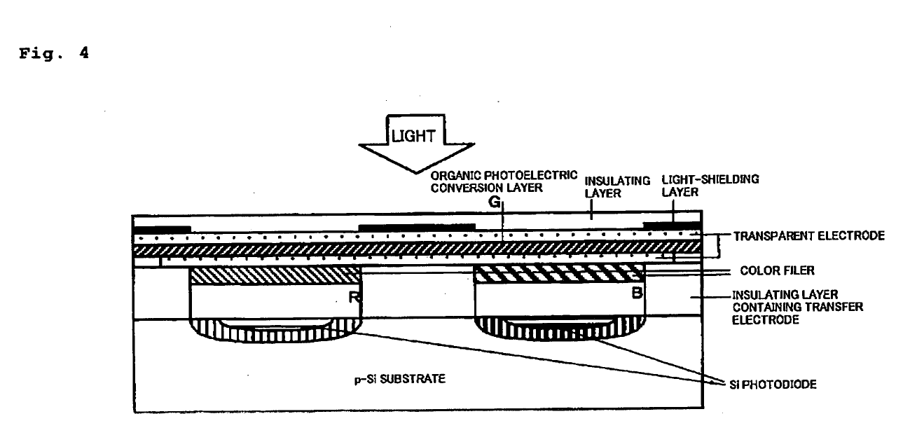

### FIG. 4

FIG. 4 shows that light receiving parts of blue light and red light are separately provided in the lower Si photoelectric conversion layer in the lateral direction but not in the depth direction. In this case, in order to achieve the separation of light between blue and red lights in Si, a color filter is provided above each of the light receiving parts. According to this figure, a configuration in which green light is received by the organic photoelectric conversion layer as the upper layer and red light and blue light are received by the lower Si is employed, but it should not be construed that the invention is limited thereto. For example, a structure in which blue light is received by the organic photoelectric conversion layer and green light and red light are received by the lower Si is employable, too. However, since the organic photoelectric conversion later layer as the upper layer is the highest with respect to the use efficiency of light, in view of visibility, it is preferable that a layer which receives green light is the organic photoelectric conversion layer as the upper layer.

### Example 6

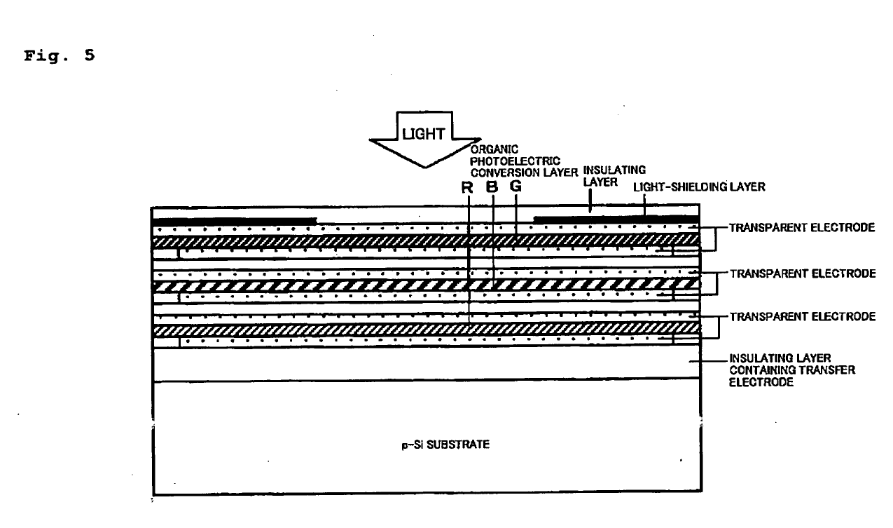

### FIG. 5

FIG. 5 shows that all of the layers which receive green, blue and red lights are configured of an organic photoelectric conversion layer. In this figure, the stacking order is green, blue and red in this order from the upper side, but it should not be construed that the invention is limited thereto. For example, a structure in which photoelectric conversion layers are stacked in the order of blue, red and green from the upper side is employable, too. However, taking into consideration an optical loss or the like in the insulating material or organic layer, since the organic photoelectric conversion layer as the upper layer is the highest with respect to the use efficiency of light, in view of visibility, it is preferable that a layer which receives green light is the organic photoelectric conversion layer closest to the light incident side.

This application is based on Japanese Patent application JP 2005-251745, filed Aug. 31, 2005, the entire content of which is hereby incorporated by reference, the same as if set forth at length.

What is claimed is:

1. An organic photoelectric conversion device comprising; a lower electrode; an organic layer; and an upper electrode provided in this order, in which at least one of the lower electrode and the upper electrode is a transparent electrode, and an electron is collected in a side of one of the lower electrode and the upper electrode and a hole is collected in the other side of the lower electrode and the upper electrode so as to read out photocurrent, wherein the electrode in the side of collecting an electron is the transparent electrode and has a work function of 4.5 eV or less.

2. The organic photoelectric conversion device according to claim 1, wherein both the lower electrode and the upper electrode are a transparent electrode.

3. The organic photoelectric conversion device according to claim 1, wherein the electrode in the side of collecting a hole has a work function of 4.5 eV or more.

4. The organic photoelectric conversion device according to claim 1, wherein the transparent electrode in the side of collecting an electron is a transparent electrode including a metal oxide layer and a metal layer having a work function of 4.5 eV or less, so that the metal oxide layer, the metal layer and the organic layer are provided in this order.

5. The organic photoelectric conversion device according to claim 4, wherein the metal oxide layer is a layer comprising ITO.

6. The organic photoelectric conversion device according to claim 4, wherein the metal layer is a layer containing In, Ag or Mg.

7. The organic photoelectric conversion device according to claim 4, wherein the metal layer has a thickness of from 0.5 to 10 nm.

8. The organic photoelectric conversion device according to claim 1, wherein the transparent electrode in the side of collecting an electron comprises Cs-doped ITO.

9. The organic photoelectric conversion device according to claim 1, wherein the transparent electrode in the side of collecting an electron comprises AZO.

10. The organic photoelectric conversion device according to claim 1, wherein the transparent electrode in the side of collecting an electron is a lower electrode resulting from a surface treatment of ITO formed on a substrate by immersing it in an alkaline solution.

11. The organic photoelectric conversion device according to claim 1, wherein the transparent electrode in the side of collecting an electron is a lower electrode resulting from a surface treatment of ITO formed on a substrate by sputtering it with Ar ions or Ne ions.

12. The organic photoelectric conversion device according to claim 1, wherein the organic layer contains a material having a quinacridone skeleton.

13. A photoelectric conversion imaging device comprising: the organic photoelectric conversion device according to claim 1; and an Si substrate having a CCD or CMOS signal transfer circuit, wherein one of the lower electrode and the upper electrode of the organic photoelectric conversion device is connected to the signal transfer circuit so as to read out a signal.

14. A photoelectric conversion device comprising: the organic photoelectric conversion device according to claim 1; and an Si substrate having a photodiode provided in an upper part thereof.

15. The photoelectric conversion device according to claim 14, wherein the photodiode including a plural number of a first conductive region and a second conductive region which is of a conductive type opposite to the first conductive region, and a junction face between the first conductive region and the second conductive region is formed in a depth suitable for photoelectrically converting mainly lights of any two wavelength regions of blue, green and red lights, respectively.

16. The photoelectric conversion device according to claim 14, wherein a plural number of the organic photoelectric conversion devices are stacked via an insulating layer.

17. A photoelectric conversion imaging device comprising the photoelectric conversion device according to claim 14, wherein the Si substrate has a CCD or CMOS signal transfer circuit, and the lower electrode or the upper electrode of the organic photoelectric conversion device is connected to the signal transfer circuit so as to read out a signal.
